(19) United States
(12) Patent Application Publication
(10) Pub. No.: US 2023/0262903 A1
(43) Pub. Date: Aug. 17, 2023

(54) INSPECTION AND PRODUCTION OF PRINTED CIRCUIT BOARD ASSEMBLIES

(71) Applicant: Siemens Aktiengesellschaft, München (DE)

(72) Inventors: Daniel Fiebag, Erlangen (DE); Alexander Kleefeldt, Erlangen (DE)

(21) Appl. No.: 18/015,226

(22) PCT Filed: Jul. 12, 2021
(86) PCT No.: PCT/EP2021/069349

§ 371 Date: Jan. 9, 2023

(30) Foreign Application Priority Data
Jul. 13, 2020 (EP) 20185488.2

(51) Int. Cl. H05K 3/00; G06T 7/00; H05K 13/08; H05K 13/04

(52) U.S. Cl. CPC H05K 3/0005; G06T 7/0004; H05K 13/083; H05K 13/0465; G06T 2207/20081; G06T 2207/30141

(57) ABSTRACT

A method of inspecting a printed circuit board (PCB) assembly includes acquiring an image of the PCB assembly and analyzing the image, wherein the analysis includes an object-based analysis of the image for recognizing at least one component placed on the PCB, wherein the object-based analysis is performed based on an object-based analysis program, and wherein the object-based analysis program includes a trained machine learning model. The method further includes: determining whether the at least one component is placed on the PCB based on a comparison between a finding of the object-based analysis and stored assembly information for the PCB; outputting an error when one or more components are missing or wrongly placed; inputting a result of a visual inspection of the PCB assembly that indicates a pseudo-error of the object-detection analysis; and writing one or more settings for soldering the PCB assembly by a soldering device.

The present patent document is a § 371 nationalization of PCT Application Serial No. PCT/EP2021/069349, filed Jul. 12, 2021, designating the United States, which is hereby incorporated by reference, and this patent document also claims the benefit of European Patent Application No. 20185488.2, filed Jul. 13, 2020.

### TECHNICAL FIELD

The present disclosure relates to printed circuit board (PCB) assemblies as well as their production by way of soldering. More particularly the present disclosure relates to the inspection of PCB assemblies during production. Furthermore, the present disclosure relates to the field of artificial intelligence and machine learning and its industrial application.

### BACKGROUND

Automated inspection of printed circuit board (PCB) assemblies is becoming more important as electronics devices get smaller and packing density gets higher. Automated inspection has better performance than manual inspection in terms of consistency, speed, and lower cost.

A printed circuit board (PCB) mechanically supports and electrically connects electrical or electronic components using conductive tracks, pads, and other features etched from one or more sheet layers of copper laminated onto and/or between sheet layers of a non-conductive substrate. Components may be soldered onto the PCB to both electrically connect and mechanically fasten them to the PCB.

The commonly found defects on a PCB assembly include missing components, misalignment, titled components, tombstoning/open circuit, wrong components, wrong value, bridging/short circuit, bent leads, wrong polarity, extra components, lifted leads, insufficient solder, excessive solder, among others.

From U.S. Pat. Application Publication No. 2015/0246404 A1, Soldering System Power Supply Unit, Control Unit, Administration Device, and Power Supply-and-Control Device have become known.

From EP 0871027 A2, inspection of print circuit board assembly has become known. From KR 20090049009 A, an optical inspection apparatus of printed circuit board and method of the same has become known.

### SUMMARY

Nowadays, due to the high variety of PCB assemblies to be produced, the workers assembling the PCBs with the electrical components are confronted with a high number of different components to be mounted on the same or similar PCB types. This may lead to faults when placing the components on a particular PCB due to the workers confusing one layout with another. A PCB assembly may only be inspected after soldering the components to the printed circuit board. Hence, leading to a lot of PCB assemblies being discarded and thus to loss of material and waste.

It is thus an object of the present disclosure to improve the use of material, to simplify the production process flow and to thereby reduce the number of defectively produced PCB assemblies.

The scope of the present disclosure is defined solely by the appended claims and is not affected to any degree by the statements within this summary. The present embodiments may obviate one or more of the drawbacks or limitations in the related art.

The object is achieved by the following aspects.

According to a first aspect, the object is achieved by a method of inspecting a printed circuit board (PCB) assembly. The method includes acquiring an image of the PCB assembly, e.g., using a camera, and analyzing the image. The analysis includes an object-based analysis of the image for recognizing at least one component placed on the PCB. The method further includes determining whether the at least one component is placed on the PCB based on a comparison between a finding of the object-based analysis and stored assembly information for the PCB.

According to a second aspect, the object is achieved by a method of training a machine learning algorithm of an object-based analysis program. The method includes acquiring a plurality of images of a PCB assembly, (e.g., for different types of PCB assemblies or during production of the PCB assembly). The method further includes selecting, from the plurality of images, images suitable for training the machine learning algorithm. The method further includes automatically labeling the plurality of images based on a template for labeling of the PCB assembly. The method further includes training the machine learning algorithm based on the labeled images.

According to a third aspect, the object is achieved by an inspection system for inspecting a printed circuit board (PCB) assembly. The system includes a camera for acquiring an image of the PCB assembly. The system further includes a control unit for analyzing the image, wherein the analysis includes an object-based analysis of the image for recognizing at least one component placed on the PCB. The control unit is further configured to determine whether the at least one component is placed on the PCB based on a comparison between a finding of the object-based analysis and stored assembly information for the PCB.

Further advantageous embodiments are provided in the dependent claims and are described in the following.

### BRIEF DESCRIPTIONS OF THE DRAWINGS

FIG. 1 depicts a plurality of acts during the production of a PCB assembly, in particular placement of electrical components and soldering of the PCB assembly.

FIG. 2 depicts an example of an automatic optical inspection during the production of a PCB assembly and after the soldering of the electrical components to the PCB.

FIG. 3 depicts a plurality of acts during the production of a PCB assembly according to a first embodiment, where the optical inspection is performed before soldering the electrical components to the PCB.

FIG. 4 depicts an image from a PCB assembly including a PCB and electrical components placed on the PCB.

FIG. 5 depicts a result of an object-detection analysis of an image of the PCB assembly.

FIG. 6 depicts an example of a system and corresponding acts for inspecting a PCB assembly.

FIG. 7 depicts an example of a system and corresponding acts for training a machine learning model in order to perform an object-detection of an image of a PCB assembly.

FIG. 8 depicts an example of a workflow for inspecting a PCB assembly and the integration of the inspection in a production of PCB assemblies.

### DETAILED DESCRIPTION

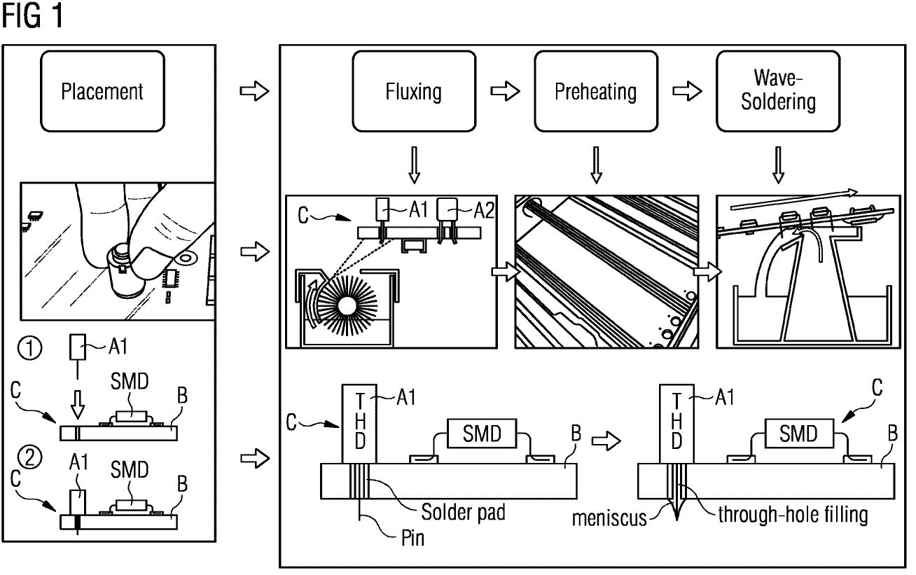

FIG. 1 shows a plurality of acts during the production of a PCB assembly C, in particular placement of electrical components A1, A2, SMD, and soldering of the PCB assembly C. For the production of a PCB assembly C, electrical components A1, A2, SMD are placed on the PCB B. For example, the electrical components A1, A2 such as through-hole devices A1, A2, (e.g., capacitors and/or integrated circuits), may be placed on the PCB B. Additionally, electrical components may be surface mount devices SMD and may also be placed on the PCB B.

Through-hole technology (THT) refers to the mounting scheme used for electronic components A1, A2 that involves the use of leads on the components that are inserted into holes drilled in PCBs C and soldered to pads on the opposite side either by manual assembly (e.g., hand placement) or by the use of automated insertion mount machines. Through-hole mounting provides strong mechanical bonds when compared to surface-mount technology.

After placing the electrical components A1, A2 on the PCB B, the PCB assembly C is subject to a soldering process. An example of a wave soldering process is illustrated in FIG. 1, wherein a flux is applied to the PCB assembly C, which is subsequently preheated. Finally, the PCB assembly C is transported over a standing wave of solder where the PCB B and the components A1, A2 make contact with the solder.

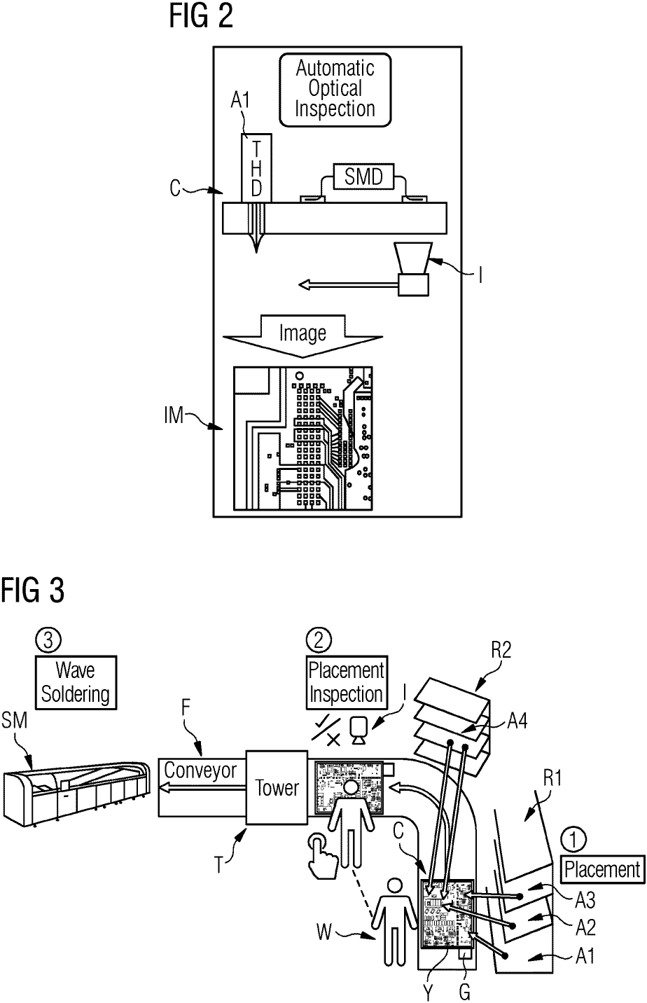

Turning to FIG. 2, an automatic optical inspection during the production of a PCB assembly C is shown. The automatic optical inspection may be performed after soldering the one or more electrical components A1, SMD to the PCB B. To that end, an image IM is taken by a camera I of the bottom side of the PCB assembly C.

As already mentioned, the rising complexity and variety of electrical devices also leads to higher requirements for the worker(s) assembling the PCBs C with electrical components A1. As the case may be, electrical components A1 may be forgotten, or the wrong component A1 may be placed on the PCB B. In such a case, the inspection of the PCB assembly C after the soldering either requires a high effort of de-soldering the PCB assembly C and removing the component(s) wrongly installed or in the worst case, the PCB assembly C needs to be discarded.

Accordingly, it is proposed to perform an automated optical inspection of the PCB assembly C after placing the one or more electrical components A1 on the PCB B and before the soldering of the electrical components A1 to the PCB B.

In FIG. 3, a plurality of acts during the production of a PCB assembly C are shown, where the optical inspection is performed before soldering the one or more electrical components A1-A4 to the PCB B.

A PCB B may arrive at a placement station 1 at which a worker may place the electrical components A1-A4 on the PCB B. The PCB B may be placed on or in a tray Y for transporting the PCB B along the production line via a conveyor F. The worker may pick the electrical components A1-A4 from one or more shelves R1, R2 at the placement station and place the components A1-A4 according to the type of PCB assembly C to be produced. Alternatively, the placement may be performed automatically, e.g., by a robot.

The wave soldering station 3 may include a single wave, not shown. In order to transport the assemblies from the placement station 1 or the inspection station 2 to the soldering station 3 a tower T for storing a plurality of PCB assemblies may be provided. The tower may serve as a buffer for loading the soldering machine, e.g., if the placement of electrical components at the placement station takes too long. Now, before leaving the placement station or before entering the soldering station 3 of the PCB assembly production an automatic optical inspection is performed at a placement inspection station 2. To that end, an image of the PCB assembly, (e.g., using a camera I), is acquired. The image is then analyzed, wherein the analysis includes an object-based analysis of the image for recognizing at least one component placed on the PCB B. Thereby, it is determined whether the at least one component is placed on the PCB B based on a comparison between a finding of the object-based analysis and stored assembly information for the PCB B. The result of the comparison may be displayed to the worker W at the inspection station 2 and/or the placement station 1 in order to exchange the wrongly placed components A-A4 or to place one or more missing components A1-A4 on the PCB B.

If it is determined by the object-detection analysis that all the electrical components are placed correctly, the PCB assembly may continue to be transported to the soldering station 3. For example, the PCB assembly C may be placed in the tower T of the soldering device at the soldering station 3.

If, however, it is determined that not all the electrical components A1-A4 are placed correctly, the PCB assembly C may not continue to the further production acts, e.g., may not continue to be transported to the soldering station 3.

For the PCB assembly C to continue to the further production acts, the automatic optical inspection is a mandatory act, (e.g., all PCBs assemblies C need to be analyzed before production may continue). In order to initiate the optical inspection, the worker may need to press a button at the inspection station 3.

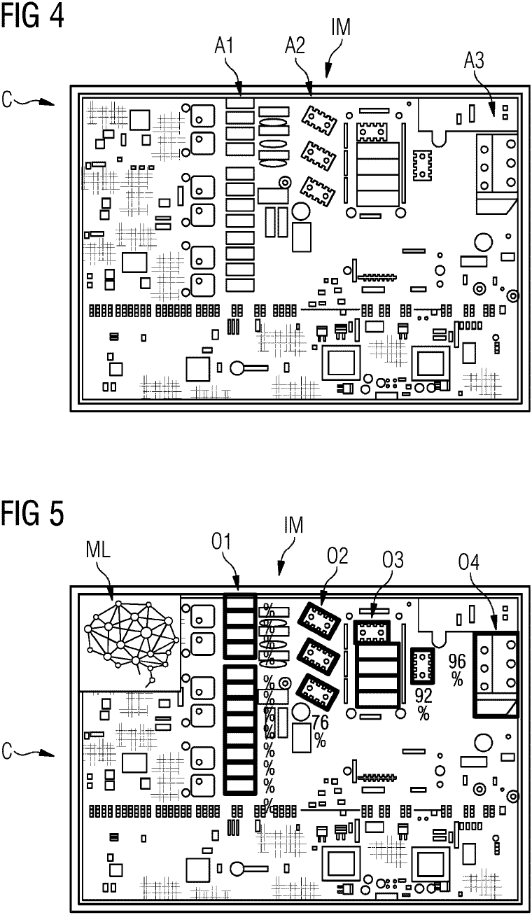

Now turning to FIG. 4, an image IM of a PCB assembly C is shown. The PCB assembly C includes a PCB B and electrical components A1-A3 placed on the PCB B, e.g., via THT. The image IM may be captured by a camera that is mounted at the inspection station 2. As seen in FIG. 4, the image IM shows the upper side of the PCB B, e.g., the side on which the electrical components A1-A3 are placed.

The image IM may be subject to an object-detection analysis for recognizing at least one component A1-A3 placed on the PCB B. The result of the object-detection analysis is shown in FIG. 5, where the objects O1-O4 identified are framed. The analysis may assign a probability of the correctness of the identification to the objects O1-O4 identified. If the probability is below a certain threshold, (e.g., below 75%), the PCB assembly C and the corresponding electrical component A1-A3 may need to be checked before production of the PCB assembly C may continue. The object-detection analysis is a computer-implemented method that serves for assigning at least one object O1-O4 to a component A1-A3 identified on the PCB B. The object-detection analysis may be performed by a trained machine learning model ML, as depicted in FIG. 5.

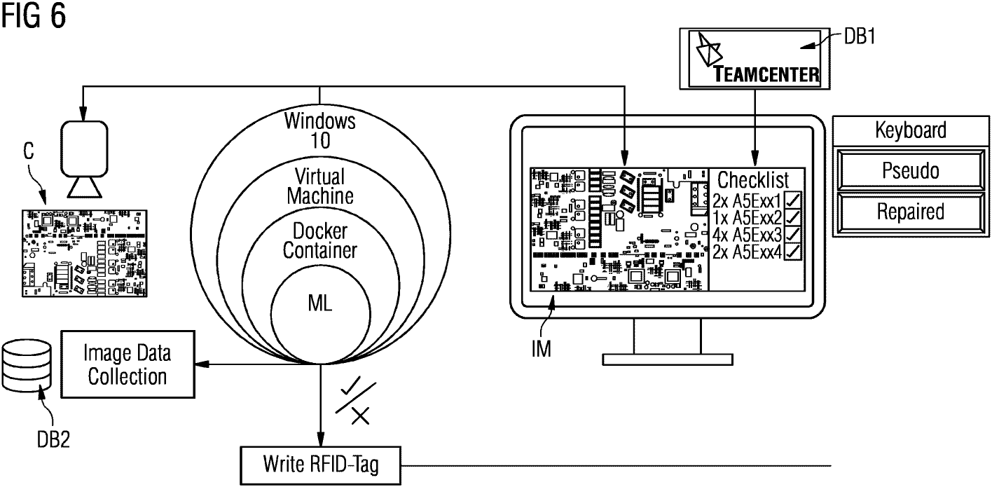

Further details of the system and corresponding acts for inspecting a PCB assembly C are shown in FIG. 6. An image IM of the PCB assembly may be captured by a camera, (e.g., at placement inspection station 2 of FIG. 3), and thus acquired for performing the object-detection. The machine learning model ML may be hosted in a virtual machine on an operating system, such as Windows™ 10. The machine learning model ML itself may be part of a container, such as a docker container, and run on the virtual machine. The image IM may be processed by the machine learning model ML and the objects identified may be overlaid on the image IM acquired and displayed, e.g., to a worker at the placement inspection station. In addition, a list of electrical components identified may be displayed to the worker on a display. The list of electrical components may be retrieved from a database DB1 or planning system, such as Teamcenter.

In case the object detection identifies all electrical components to be placed on the PCB, the PCB assembly may continue to the next production act. To that end, a result of the inspection may be written on a tag G. For example, one or more settings for the subsequent act of soldering the PCB assembly may be written on the tag. The tag G may be attached to a tray Y the PCB assembly is located on. For example, the tag G may be an RFID-tag, including a re-writeable memory. In particular, the PCB type or an identifier of the PCB may be written on the tag. The PCB assembly may then be transported to the soldering station, (e.g., as shown in FIG. 3), where the PCB type and/or the PCB identifier may be read from the tag. Based on the setting(s) on the tag G, the soldering device may adapt the soldering process. In order to control the soldering process, the soldering device may include a soldering program. A setting for a soldering program may include a temperature setting for a part of a soldering device, (e.g. a soldering iron, tweezers, micro tweezers, de-soldering iron, and hot air, etc.).

In case the object detection does not identify all electrical components to be placed on the PCB, the process is halted, and the PCB assembly is repaired, (e.g., by exchanging one or more electrical components on the PCB or by placing one or more additional components on the PCB). After repairing the PCB assembly, a new image of the PCB assembly is acquired, and the object-detection is re-run for the repaired PCB assembly. In such a case, a corresponding code may be written on the tag or the field for identifying the PCB and/or the corresponding settings for soldering may (intentionally) be left empty. Then, the production may be halted, e.g., at least interrupted when the PCB assembly arrives at the soldering station such as at the location the tag on the tray is read out. In such a case, the worker may need to remove the PCB assembly from the tray before the production process may continue.

Instead of repairing the PCB assembly as just described, the case may appear that the object-detection analysis is at fault. That is to say, the object-detection analysis may determine that one or more components are missing or that one or more wrong components have been placed on the PCB. In that case, the worker may identify a pseudo-error, by acquitting a corresponding (virtual) button. Thereafter, one or more settings for soldering the PCB assembly by a soldering device may be written on the tag.

Thus, as mentioned above, the object-detection analysis is a computer implemented method for image processing that serves to detect instances of one or more (e.g., semantic) objects of a certain class in one or more (e.g., digital) images. A machine learning model ML, in the form of a computer program, may be used for the object-detection analysis. For example, the object-detection analysis may be used to detect one or more components placed on the PCB. As a result, the object-detection analysis may provide an identifier and coordinates that represents each component detected on the PCB. Then, the results of the object-detection analysis may be compared with the assembly information for the PCB, e.g., a bill of materials (BOM). The assembly information may be a list of components needed to manufacture the PCB assembly. Thus, by comparing the objects found by the object-detection analysis with the assembly information one or more missing components may be found. Furthermore, it may be determined that one or more wrong components have been placed on the PCB. Still further, wrong placement of the one or more components on the PCB may be found.

For example, the assembly information may be provided in the form of a file, (e.g., an XML file), including a list of components and coordinates associated with each component for the PCB assembly to be manufactured. An exemplary excerpt of assembly information that may be stored in the form of a file is provided in the following:

<object>
<name>component_1</name>
<bndbox>
<xmin>1005</xmin>
<ymin>81</ymin>
<xmax>1029</xmax>
<ymax>103</ymax>
</bndbox>
</object>
<object>
<name>component_2</name>
<bndbox>
<xmin>360</xmin>
<ymin>288</ymin>
<xmax>383</xmax>
<ymax>318</ymax>
</bndbox>
</object>

Here, the components component_1 and component_2 are part of the PCB assembly to be manufactured and are assigned corresponding coordinates given by the bounding boxes “bnbdbox”. Therein, the coordinates represent the position of corresponding component on the PCB, e.g., relative to a reference point on the PCB. For example, a PCB and thus the image of the PCB may include one or more reference points. Such a reference point is also known by the term reference mark or mark point.

As an outcome of the comparison between the finding of the object-detection analysis and the assembly information placement of the components on the PCB may thus be checked.

The case may appear that by way of the comparison it is determined, (e.g., by the object-detection analysis), that one or more components are missing or that one or more wrong components have been placed on the PCB or have been placed wrongly on the PCB. This may be the case when there is no agreement between the objects found by the object-based analysis and the assembly information provided. In that case, the outcome or result of the comparison may be output, e.g., displayed on a display of an inspection station. The output may include error information relating to the missing or wrong component or the wrongly placed component. For example, the objects identified may be overlaid on the image acquired and displayed, e.g., to a worker at the (placement) inspection station. The error information may be in the form of colored rectangles or boxes identifying the missing, misplaced, or wrong components. The error information may be displayed on the display of the inspection station, (e.g., it may be overlayed on the image of the printed circuit board). Alternatively, or additionally, the error information may identify the missing, misplaced, or wrong components in the form of text, (e.g., saying “component_1”).

In addition, a label indicating pass or fail may be displayed to a worker, (e.g., at the inspection station). The label indicates an error in the placement of components of the PCB assembly. The label may be associated with the image.

The PCB assembly may then be inspected by an operator, also denoted as worker, by visual inspection of the PCB assembly. The operator may thus determine by visual inspection whether the error detected by the object-detection analysis is a true error or a pseudo-error. To that end, an input file is provided in the display. The operator may input the result of the visual inspection by acquitting, (e.g., pressing), a corresponding (e.g., virtual) button at the inspection station, (e.g., via a display at the inspection station).

In case of a pseudo-error, the image label may be changed from error to pass or to pseudo-error. This allows the manufacturing of the PCB assembly to continue. Hence, one or more settings for soldering the PCB assembly by a soldering device may then be written, for example on a tag that may be attached to a tray the PCB assembly is located on, e.g., based on the result of the visual inspection. Thus, writing of the one or more settings may be based on the result of the visual inspection of the worker.

In a case a true error has been found by the visual inspection by the worker, the misplacement may be corrected by the worker and the manufacturing of the PCB may also continue by writing one or more settings for soldering the PCB assembly by a soldering device on a tag that may be attached to a tray the PCB assembly is located on. Hence, no faulty or defective PCB assembly are manufactured. Furthermore, an improved labelling of the image of the PCB assembly is obtained

Now, if a true error has been found by the visual inspection of the worker, the object-detection analysis may be performed again in order for the worker to obtain a feedback on whether the repair measure, e.g., the re-placement of the one or more components, has succeeded. Hence, a new finding or result of the object-detection is obtained and displayed to the worker which may then again acquit the (e.g., virtual) button at the inspection station, e.g., confirming that the component is now correctly placed or that pseudo-error has occurred again.

In addition, to the object-detection the image of the PCB assembly acquired may be stored in a database DB2. The images stored in the database DB2 may serve for (re-)training the machine learning model ML used for the object-detection analysis. Hence, a plurality of images IM may be acquired during the production of PCB assemblies C in order to (re-)train the machine learning model ML.

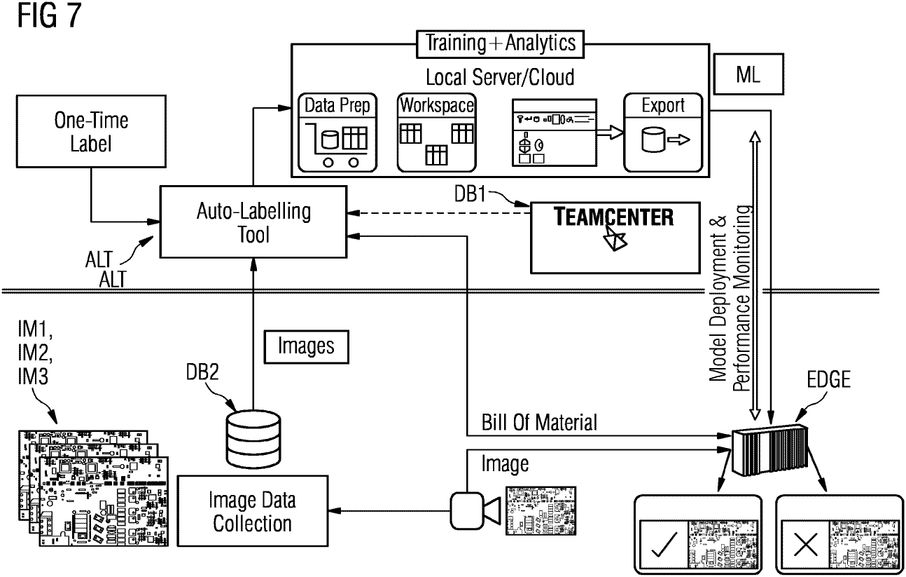

Turning to FIG. 7, a system and corresponding acts for training a machine learning model ML in order to perform an object-detection of an image of a PCB assembly C is shown. During production of PCB assemblies, images IM1, IM2, IM3 of the PCB assemblies C assembled may be captured and stored in a database DB2 for the purpose of image data collection. In order to effortlessly label the images IM1, IM2, IM3 and use them for training of a machine learning model ML, the images IM1, IM2, IM3 may be loaded into or read by an auto-labelling tool ALT. The auto-labeling tool ALT carries out the labeling of the images IM1, IM2, IM3. Instead of labeling all of the images IM1, IM2, IM3 acquired manually a one-time label is used. To that end, a template is used for labeling the images IM1, IM2, IM3. The auto-labelling may be based on a template matching algorithm, which detects the offset of the PCB (of the template image) relative to the image boundaries for each of the images IM1, IM2, IM3. Doing this, the labels defined in the template image are transferred from image-coordinate-system to PCB-coordinate-system (of the template) for each image, thereby allowing the algorithm to auto-label every image in the database DB2 and to subsequently use the auto-labeled images for training the ML object-detection algorithm. For example, one or more reference points may be detected on each one of the images. Based on the one or more reference points the template may be arranged.

The template may include one or more predetermined or preset coordinates that serve for identifying one or more components. Similarly, as described in the above with respect to the assembly information, the template may have the form of a file, e.g., an XML file. An excerpt of a template is shown in the following:

<object>
<name>component_1</name>
<bndbox>
<xmin>1005</xmin>
<ymin>81</ymin>
<xmax>1029</xmax>
<ymax>103</ymax>
</bndbox>
</object>
<object>
<name>component_2</name>
<bndbox>
<xmin>360</xmin>
<ymin>288</ymin>
<xmax>383</xmax>
<ymax>318</ymax>
</bndbox>
</object>

Now, in order to automatically match the template with each one of the images (and thus to label the components within the images) an offset may be calculated using the reference points of each image, respectively. The offset may be calculated based on the distance of the one or more reference points of an image relative to one or more image boundaries, e.g., for each of the images IM1, IM2, IM3, respectively. Thereby, the position, (e.g., the coordinates), of the one or more components in each image are determined and the automatic labeling of the components in the image is thus performed. As may be seen by the four coordinates of each component, a box or rectangle is defined by way of which the position of each component in the image is identified. Alternatively, the image boundaries may be adjusted in order for the image boundaries to coincide with the reference points in the image. The adjustment of the coordinates of the template may be necessary due to the placement and thus position of the PCB in a tray. This is the case, because the position of each PCB in the respective tray is different.

The template for labeling may be an image that has been labeled manually. The labeling of the template is then transferred by the auto-labeling tool to the one or more images IM1, IM2, IM3 previously stored in the database DB2. Hence, the images IM1, IM2, IM3 acquired do not have to be labeled manually, but rather suitable images for the auto-labeling are chosen to be stored in the database DB2. Choosing suitable images may be automated according to one or more pre-determined criteria or may be done manually by a user. Hence, the labeling associated one or more objects detected in the image with one or more electrical components.

Once the images IM1, IM2, IM3 are labeled, (e.g., the objects or electrical components identified), the machine learning model may be (re-)trained based on the now labeled images IM1, IM2, IM3.

After training the machine learning model ML, the model ML may be deployed on an industrial PC or integrated into the production system for producing one or more PCB assemblies, e.g., integrated in an existing infrastructure. For example, the machine learning model ML may be deployed on a control unit of an inspection system, e.g., for controlling the placement inspection station. The inspection system or inspection station may itself be integrated into a production system for producing PCB assemblies. The production system including, e.g., placement station, inspection station and soldering station, for example as FIG. 3.

As shown in FIG. 7, the auto-labeling tool ALT may obtain information of electrical components, e.g., in form of a list, for a specific PCB assembly or a plurality of PCB assemblies of a specific type from a database DB1 or planning system, such as Teamcenter or NX. The information may be used to label the one or more images IM1, IM2, IM3 in the database DB1 by the auto-labeling tool ALT. The auto-labeling tool ALT is a software program that includes suitable interfaces, e.g., APIs, to the database DB1, the database or planning system DB2 and the inspection and/or production system. Thus, the auto-labeling may be computer program. That is to say, the auto-labeling is a computer implemented method.

Hence, once deployed, e.g., as shown in FIG. 7, on an edge device EDGE, the machine learning model ML may receive images from the camera C at the inspection station and may also receive a Bill of Materials, e.g., from the database or planning system DB1, for example via the auto-labeling tool ALT, related to the PCB assembly C as captured on the image acquired. The machine learning model ML may then determine one or more components A1-A4 as present in the bill of materials, BOM, in the image of the PCB assembly acquired.

A bill of materials or product structure (sometimes bill of material, BOM or associated list) is a list of the raw materials, sub-assemblies, intermediate assemblies, subcomponents, parts, and the quantities of each needed to manufacture an end product. In general, assembly information for the PCB assembly may be obtained by the machine learning model ML. For example, a list of components to be placed on the PCB may be stored within the production system, the inspection station, or the edge device.

Accordingly, the machine learning model ML may infer whether a PCB assembly as captured on the image processed is fully equipped or is missing one or more electrical components or whether the wrong electrical components have been placed on the PCB.

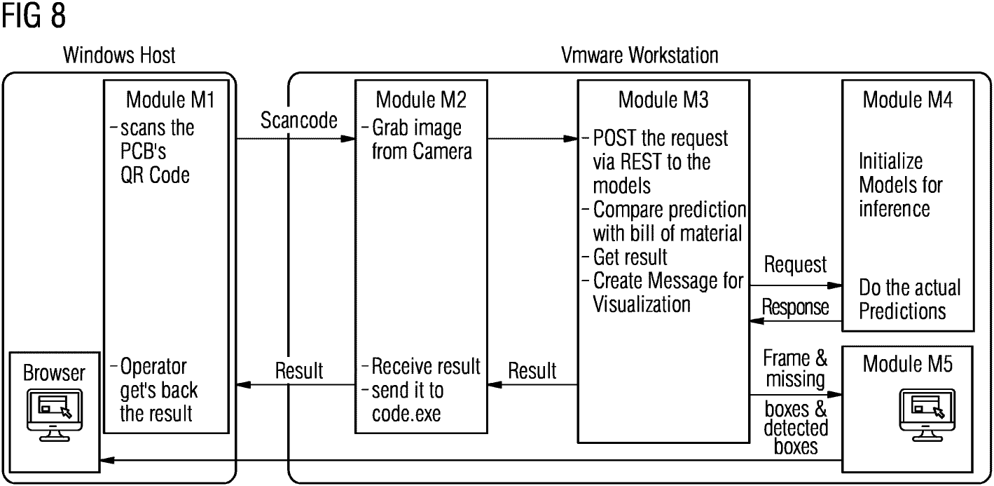

Now turning to FIG. 8, a workflow for inspecting a PCB assembly and the integration of the inspection in a production (line) of PCB assemblies is shown.

The workflow may be implemented by one or more software program modules M1-M5. The first module M1 may run directly on an operating system and may serve for scanning an identifier of the PCB assembly. For example, the first module may serve for identifying the PCB assembly based on an identifier, e.g. a 2D-barcode, arranged on the PCB assembly, wherein the identifier serves for identifying an object-based analysis program from a plurality of object-based analysis programs for recognizing at least one component placed on the PCB.

The identifier may then be transmitted to the second module M2. The second module M2 may acquire an image (grab a frame) from the camera at the inspection station.

The identifier and the image may then be transmitted to a third module M3 that retrieves the bill of material or other assembly information, (e.g., including the electrical components to be place on the PCB assembly), for the PCB assembly to be assembled, (e.g., based on the identifier).

Further, the image and the identifier may be transmitted to a fourth module M4. The fourth module may select, e.g., based on the identifier, the suitable machine learning model from a plurality of machine learning models, wherein each of the plurality of machine learning models is configured to a specific PCB assembly, (e.g., a PCB assembly type), and hence trained in order to identify the components for said specific PCB assembly type. Having selected the suitable machine learning model the inference may be performed by the machine learning model. The inference may include object-detection based on the image received. Having completed the object-detection and associated the corresponding electrical components on the image, the components identified may transmitted to the third module M3 again, where the electrical components identified are compared to the bill of materials as previously received.

For the purpose of visualization, frames may be added to the objects detected on the image processed, as previously described, using a fifth module M5. Also missing components may be visualized by adding a frame to the part of the image of the PCB assembly where the missing component may be placed or where the faulty component is placed on the PCB assembly.

The result of the comparison between the components identified by the object detection analysis and the assembly information from the third module M3 may be transmitted to the second module M2 from where it is forwarded to the first module M1. The result of the comparison may for example be pass or fail, (e.g., a binary result).

The modules M1-M5 may be combined with one another to form either a single module or that the functions may be split differently between the modules or that the functions of the modules may be combined to another number of modules.

Finally, the result may be displayed for example in a browser. As may be seen in FIG. 8, the visualization of module M5 may be exposed to the host operating system.

The result of said comparison may subsequently be used to control the further production acts of the PCB assembly. That is to say, as described in the above, that settings or other information may be written, based on result of the comparison, on a tag of the tray Y which the PCB assembly is transported. Said settings may serve to control the further production acts of the PCB assembly. For example, the soldering of the PCB assembly may be controlled.

Further exemplary embodiments are described in the following:

According to a first embodiment, a method of inspecting a printed circuit board, PCB, assembly (C) is provided the method includes: acquiring an image (IM) of the PCB assembly (C), e.g., using a camera, and analyzing the image (IM), wherein the analysis includes an object-based analysis of the image (IM) for recognizing at least one component (A) placed on the PCB (B), and determining whether the at least one component (A) is placed on the PCB (B) based on a comparison between a finding of the object-based analysis and stored assembly information for the PCB (B).

In a second embodiment, the method according to the first embodiment includes writing based on a result of the comparison, one or more settings for soldering, by a soldering device, the PCB assembly (C), wherein the settings may include a PCB type and/or a PCB ID.

In a third embodiment, the method according to any one of the preceding embodiments includes loading, based on a result of the comparison, one or more settings for soldering, by a soldering device, the PCB assembly (C).

In a fourth embodiment, the method according to any one of the preceding embodiments includes preventing writing, based on a result of the comparison, of one or more settings for soldering the PCB assembly (C) by a soldering device.

In a fifth embodiment, the method includes halting, based on a result of the comparison, production of the PCB assembly (C).

In a sixth embodiment the method according to any one of the preceding embodiments includes: identifying, based on the comparison, at least one missing component on the PCB assembly (C), and optionally repairing the PCB assembly (C) according to the determined missing component; and writing, based on a result of the comparison, one or more settings for soldering the PCB assembly (C) by a soldering device.

In a seventh embodiment, the method according to any one of the preceding embodiments includes identifying, based on a result of the comparison, a pseudo-error, and writing, based on a result of the comparison, one or more settings for soldering the PCB assembly (C) by a soldering device.

In an eighth embodiment, the method according to any one of the preceding embodiments includes arranging the PCB assembly (C) on a tray (Y), wherein the tray (Y) includes a re-writeable memory (G), e.g., a RFID tag, for storing one or more settings.

In a ninth embodiment, the method according to any one of the preceding embodiments includes identifying the PCB assembly based on an identifier, e.g. a 2D-barcode, arranged on the PCB assembly, wherein the identifier serves for identifying an object-based analysis program from a plurality of object-based analysis programs for recognizing at least one component placed on the PCB (B).

In a tenth embodiment, the method according to any one of the preceding embodiments, the object-based analysis program includes a trained machine learning model (ML).

In an eleventh embodiment, the method according to any one of the preceding embodiments includes producing PCB assemblies (C) of different types and loading an object-based analysis program based on the PCB assembly (C) typed identified by the identifier.

In a twelfth embodiment, the method according to any one of the preceding embodiments includes receiving stored assembly information for the PCB (B), e.g., in form of a bill of materials, from an engineering or planning system, e.g., TEAMCENTER, for production of the PCB assembly (C).

In a thirteenth embodiment, a method of training a machine learning model (ML) of an object-based analysis program, includes: acquiring a plurality of images of a PCB assembly (C), (e.g., for different types of PCB assemblies (C) or during production of the PCB assembly); selecting, from the plurality of images (IM1, IM2, IM3), images suitable for training the machine learning model; automatically labeling the plurality of images (IM1, IM2, IM3) based on a template for labeling of the PCB assembly (C); and training the machine learning model (ML) based on the labeled images (IM1, IM2, IM3).

In a fourteenth embodiment, an inspection system (2) for inspecting a printed circuit board (PCB) assembly includes: a camera (I) for acquiring an image (IM) of the PCB assembly (C) and a control unit for analyzing the image, wherein the analysis includes an object-based analysis of the image for recognizing at least one component (A1-A4) placed on the PCB (B), the control unit further serves for determining whether the at least one component (A1-A4) is placed on the PCB (B) based on a comparison between a finding of the object-based analysis and stored assembly information for the PCB (B).

In a fifteenth embodiment, a production system (1, 2, 3) for producing printed circuit board assemblies (C) includes the inspection system (2) according to the preceding embodiment and a soldering device (3) that is connected to the inspection system.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method of inspecting a printed circuit board (PCB) assembly, the method comprising:
acquiring an image of the PCB assembly and analyzing the image, wherein the analyzing comprises an object-based analysis of the imagefor recognizing at least one component placed on the PCB, wherein the object-based analysis is performed based on an object-based analysis program, and wherein the object-based analysis program comprises a trained machine learning models;
determining, by the object-based analysis program, whether the at least one component is placed on the PCB based on a comparison between a finding of the object-based analysis and stored assembly information for the PCB;
outputting, by the object-based analysis program, an error in case that it is determined by object-detection analysis that one or more components are missing or wrongly placed or that one or more wrong components have been placed on the PCB;
inputting or receiving, a result of a visual inspection of the PCB assembly, indicating a pseudo-error of the object-detection analysis; and
writing one or more settings for soldering the PCB assembly by a soldering device.

2. The method of claim 1, wherein the one or more settings comprise a PCB type and/or a PCB ID.

3. The method of claim 1, further comprising:
loading, based on a result of the comparison, the one or more settings for soldering, by the soldering device, the PCB assembly.

4. The method comprising of claim 1, further comprising:
preventing writing, based on a result of the comparison, of at least one setting of the one or more settings.

5. The method of claim 1, further comprising:
halting, based on a result of the comparison, production of the PCB assembly.

6. The method of claim 1, further comprising:
identifying, based on the comparison, at least one missing component on the PCB assembly; and
repairing the PCB assembly according to the identified at least one missing component.

7. The method of claim 1, further comprising:
identifying, based on a result of the comparison, the pseudo-error.

8. The method of claim 1, further comprising:
arranging the PCB assembly on a tray,
wherein the tray comprises a re-writeable memory for storing the one or more settings.

9. The method of claim 1, further comprising:
identifying the PCB assembly based on an identifier, arranged on the PCB assembly,
wherein the identifier serves for identifying the object-based analysis program from a plurality of object-based analysis programs for recognizing the at least one component placed on the PCB.

10. The method claim 1, further comprising:
producing PCB assemblies of different types and loading the object-based analysis program based on the PCB assembly type identified by the identifier.

11. The method of claim 1, further comprising:
receiving stored assembly information for the PCB from an engineering or planning system for production of the PCB assembly.

12. A computer-implemented method of training a machine learning model of an object-based analysis program, the method comprising the:
acquiring a plurality of images of a PCB assembly;
selecting, from the plurality of images images suitable for training the machine learning models;
automatically labeling the plurality of images based on a template for labeling of the PCB assembly by adjusting one or more predetermined coordinates of the template based on one or more reference points of each image, wherein the predetermined coordinates relate to one or more components of the PCB assembly; and
training the machine learning model based on the labeled plurality of images.

13. An inspection system for inspecting a printed circuit board (PCB) assembly, the inspection system comprising:
a camera for acquiring an image of the PCB assembly; and
a control unit for analyzing the image, using an object-based analysis of the image for recognizing at least one component placed on the PCB, wherein the object-based analysis is configured to be performed based on an object-based analysis program, and wherein the object-based analysis program comprises a trained machine learning model,
wherein the control unit is configured to:
determine whether the at least one component is placed on the PCB based on a comparison between a finding of the object-based analysis and stored assembly information for the PCB;
output, by the object-based analysis program, an error in case that it is determined by object-detection analysis that one or more components are missing or wrongly placed or that one or more wrong components have been placed on the PCB;
receive a result of a visual inspection of the PCB assembly, the result of the visual inspection indicating a pseudo-error of the object-detection analysis; and
write one or more settings for soldering the PCB assembly by a soldering device.

14. A production system for producing a printed circuit board (PCB) assembly, the production system comprising:
an inspection system; and
a soldering device that is connected to the inspection system,
wherein the inspection system comprises:
a camera for acquiring an image of the PCB assembly; and
a control unit for analyzing the image using an object-based analysis of the image for recognizing at least one component placed on the PCB, wherein the object-based analysis is configured to be performed based on an object-based analysis program, and wherein the object-based analysis program comprises a trained machine learning model,
wherein the control unit is configured to:
determine whether the at least one component is placed on the PCB based on a comparison between a finding of the object-based analysis and stored assembly information for the PCB;
output, by the object-based analysis program, an error in case that it is determined by object-detection analysis that one or more components are missing or wrongly placed or that one or more wrong components have been placed on the PCB;
receive a result of a visual inspection of the PCB assembly, the result of the visual inspection indicating a pseudo-error of the object-detection analysis; and
write one or more settings for soldering the PCB assembly by the soldering device.

15. The production system of claim 14, wherein the control unit is further configured to:
display the image of the PCB assembly and error information relating to the missing or wrongly placed component or the one or more wrong components placed on the PCB.

16. The inspection system of claim 13, wherein the control unit is further configured to:
display the image of the PCB assembly and error information relating to the missing or wrongly placed component or the one or more wrong components placed on the PCB.

17. The method of claim 1, wherein the image of the PCB assembly is acquired using a camera.

18. The method of claim 1, further comprising:
displaying the image of the PCB assembly and error information relating to the missing or wrongly placed component or the one or more wrong components placed on the PCB.

19. The method of claim 12, wherein the plurality of images is for different types of PCB assemblies.

20. The method of claim 12, wherein the plurality of images is acquired during production of the PCB assembly.
